(19) United States
(12) Patent Application Publication
(10) Pub. No.: US 2025/0260384 A1
(43) Pub. Date: Aug. 14, 2025

(54) ACOUSTIC WAVE DEVICE

(71) Applicant: Murata Manufacturing Co., Ltd., Nagaokakyo-shi (JP)

(72) Inventors: Hiromu OKUNAGA, Nagaokakyo-shi (JP); Sena SUZUKI, Nagaokakyo-shi (JP)

(21) Appl. No.: 19/192,603

(22) Filed: Apr. 29, 2025

Related U.S. Application Data
(63) Continuation of application No. PCT/JP2023/037687, filed on Oct. 18, 2023.

(30) Foreign Application Priority Data
Nov. 14, 2022 (JP) 2022-181810

(51) Int. Cl. H03H 9/25; H03H 9/02; H03H 9/64

(52) U.S. Cl. CPC H03H 9/25; H03H 9/02818; H03H 9/02574; H03H 9/6483

(57) ABSTRACT

An acoustic wave device includes a piezoelectric substrate including a piezoelectric layer and a support substrate stacked on a second main surface side of the piezoelectric layer, a first electrode layer between the support substrate and the piezoelectric layer and not connected to a signal potential, and an IDT electrode on a first main surface of the piezoelectric layer and including electrode fingers. A region where adjacent electrode fingers overlap each other is a crossing region. The first electrode layer is provided at a position overlapping the crossing region in plan view. The piezoelectric substrate includes a first formation region overlapping the crossing region and the first electrode layer and a first non-formation region overlapping the crossing region and not overlapping the first electrode layer, and the first non-formation region overlaps a portion between the adjacent electrode fingers.

### CROSS REFERENCE TO RELATED APPLICATIONS

This application claims the benefit of priority to Japanese Patent Application No. 2022-181810 filed on Nov. 14, 2022 and is a Continuation Application of PCT Application No. PCT/JP2023/037687 filed on Oct. 18, 2023. The entire contents of each application are hereby incorporated herein by reference.

### BACKGROUND OF THE INVENTION

### 1. Field of the Invention

The present invention relates to acoustic wave devices.

### 2. Description of the Related Art

To date, acoustic wave devices have been widely used in filters of mobile phones and the like. Japanese Unexamined Patent Application Publication No. 2002-151996 discloses an example of a surface acoustic wave element as an acoustic wave device. In the surface acoustic wave element, a metal layer is formed on a rigid substrate. A Zno layer is provided on the rigid substrate and on the metal layer. An IDT (Interdigital Transducer) is provided on the Zno layer. A pair of grating reflectors are provided on both sides of the IDT. Moreover, a wiring electrode is provided on the Zno layer so as to face the metal layer.

However, a substrate corresponding to the rigid substrate described in Japanese Unexamined Patent Application Publication No. 2002-151996 may have a defect. A fault may occur in an element including a defective substrate, and production efficiency may decrease.

### SUMMARY OF THE INVENTION

Example embodiments of the present invention provide acoustic wave devices each of which are able to be identified if the acoustic wave devices include a defective substrate and that are each able to reduce or prevent a fault in a product.

An acoustic wave device according to an example embodiment of the present invention includes a piezoelectric substrate including a piezoelectric layer including a first main surface and a second main surface facing each other and a support substrate stacked on the second main surface side of the piezoelectric layer, at least one first electrode layer between the support substrate and the piezoelectric layer and not connected to a signal potential, and an IDT electrode on the first main surface of the piezoelectric layer and including a plurality of electrode fingers. When an electrode finger extending direction is defined as a direction in which the plurality of electrode fingers extend and the IDT electrode is seen from a direction orthogonal or substantially orthogonal to the electrode finger extending direction, a region where electrode fingers of the plurality of electrode fingers that are adjacent to each other overlap is a crossing region. The first electrode layer is provided at least at a position that overlaps the crossing region in plan view. The piezoelectric substrate includes a first formation region that overlaps the crossing region and overlaps the first electrode layer in plan view and a first non-formation region that overlaps the crossing region and does not overlap the first electrode layer in plan view, and the first non-formation region overlaps in plan view at least one of portions between the electrode fingers that are adjacent to each other.

Acoustic wave devices according to example embodiments of the present invention are each able to be identified if the acoustic wave devices include a defective substrate and are each able to reduce or prevent a fault in a product.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic sectional view taken along line I-I in FIG. 1.

FIG. 3 is a schematic plan view illustrating each region in the first example embodiment of the present invention.

FIG. 4 is a schematic plan view of an acoustic wave device according to a comparative example.

FIG. 5 is a schematic plan view of an acoustic wave device according to a modification of the first example embodiment of the present invention.

FIG. 6 is a schematic plan view of an acoustic wave device according to a second example embodiment of the present invention.

FIG. 7 is a schematic plan view illustrating each region in the second example embodiment of the present invention.

FIG. 8 is a schematic bottom view illustrating the configuration of a first electrode layer and a second electrode layer in a third example embodiment of the present invention.

FIG. 9 is a schematic bottom view illustrating the configuration of a first electrode layer and a second electrode layer in a fourth example embodiment of the present invention.

FIG. 10 is a schematic front sectional view of an acoustic wave device according to a fifth example embodiment of the present invention.

FIG. 11 is a circuit diagram of a filter device according to a sixth example embodiment of the present invention.

FIG. 12 illustrates the impedance frequency characteristics of an acoustic wave resonator including a first electrode layer and a second electrode layer and an acoustic wave resonator not including a first electrode layer and a second electrode layer in the sixth example embodiment of the present invention.

FIG. 13 is a schematic plan view of an acoustic wave device according to a seventh example embodiment of the present invention.

FIG. 14 is a schematic plan view illustrating each region near a portion overlapping a first electrode layer in plan view and first imaginary lines in the seventh example embodiment of the present invention.

FIG. 15 is a schematic plan view illustrating each region near a portion overlapping the first electrode layer in plan view, second imaginary lines, and a third imaginary line in the seventh example embodiment of the present invention.

FIG. 16 is a schematic plan view illustrating each region near a portion overlapping a first electrode layer in plan view, a third imaginary line, and some uniform portions in a first modification of the seventh example embodiment of the present invention.

FIG. 17 is a schematic plan view illustrating each region near a portion overlapping a first electrode layer in plan view, a third imaginary line, and some uniform portions in a second modification of the seventh example embodiment of the present invention.

FIG. 18 is a schematic plan view of an acoustic wave device according to an eighth example embodiment of the present invention.

FIG. 19 is a schematic sectional view taken along line II-II in FIG. 18.

FIG. 20 is a schematic plan view of a filter device according to a ninth example embodiment of the present invention.

### DETAILED DESCRIPTION OF THE EXAMPLE EMBODIMENTS

Hereafter, the present invention will be clarified by describing example embodiments of the present invention with reference to the drawings.

Each example embodiment of the present invention described in the present specification is an example, and it is possible to replace or combine some elements or features between different example embodiments.

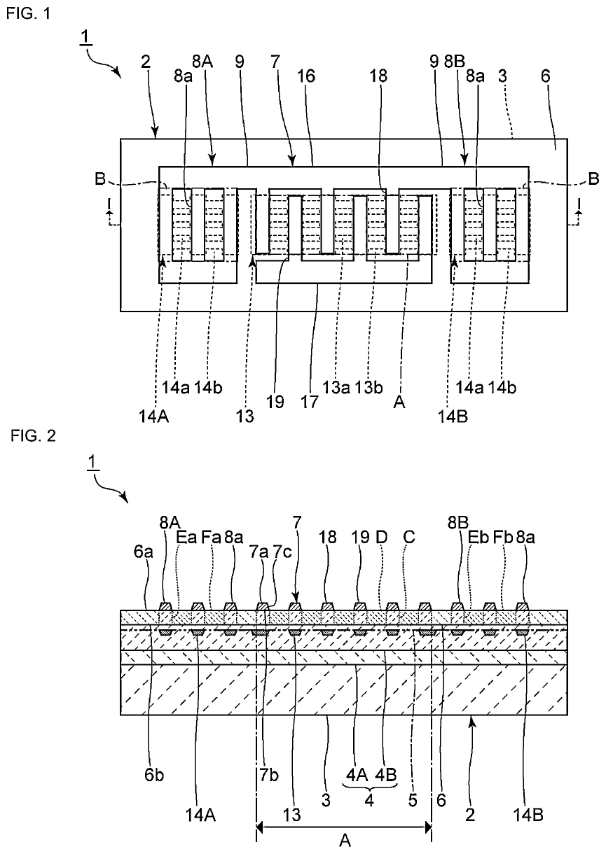

FIG. 1 is a schematic plan view of an acoustic wave device according to a first example embodiment of the present invention. FIG. 2 is a schematic sectional view taken along line I-I in FIG. 1. In FIG. 2, the boundaries between a first formation region, a first non-formation region, a second formation region, and a second non-formation region described below are indicated by broken lines, and these regions are shown by different hatching patterns. The same applies to schematic sectional views other than FIG. 2.

An acoustic wave device 1 illustrated in FIGS. 1 and 2 is an acoustic wave resonator. The acoustic wave device 1 is used, for example, in a band-pass filter, a multiplexer, a high-frequency front-end circuit, or the like. Products in which the acoustic wave device 1 is used are not limited to the above.

As illustrated in FIG. 2, the acoustic wave device 1 includes a piezoelectric substrate 2. The piezoelectric substrate 2 includes a support substrate 3, an intermediate layer 4, a dielectric layer 5, and a piezoelectric layer 6. That is, “piezoelectric substrate” refers to a substrate having piezoelectricity. The support substrate 3, the intermediate layer 4, the dielectric layer 5, and the piezoelectric layer 6 are stacked in this order. The intermediate layer 4 is a multilayer body. To be specific, the intermediate layer 4 includes a first layer 4A and a second layer 4B. The first layer 4A is provided on the support substrate 3. The second layer 4B is provided on the first layer 4A. The second layer 4B and the dielectric layer 5 are integrally made of the same material. In FIG. 2, the boundary between the second layer 4B and the dielectric layer 5 is shown by a two-dot chain line. However, the second layer 4B and the dielectric layer 5 may be independently made of different materials. The intermediate layer 4 may be a single-layer dielectric film or the like.

The piezoelectric layer 6 includes a first main surface 6a and a second main surface 6b. The first main surface 6a and the second main surface 6b face each other. The dielectric layer 5, the intermediate layer 4, and the support substrate 3 are stacked on the second main surface 6b side, among the first main surface 6a side and the second main surface 6b side. It is sufficient that the piezoelectric substrate 2 includes at least the support substrate 3 and the piezoelectric layer 6.

An IDT electrode 7 and a pair of reflectors 8A and 8B are provided on the first main surface 6a of the piezoelectric layer 6. An acoustic wave is excited when an alternating-current voltage is applied to the IDT electrode 7. The acoustic wave device 1 according to the present example embodiment is a surface acoustic wave resonator.

To be more specific, as illustrated in FIG. 1, the IDT electrode 7 includes a first busbar 16, a second busbar 17, a plurality of first electrode fingers 18, and a plurality of second electrode fingers 19. The first busbar 16 and the second busbar 17 face each other. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other. The first electrode fingers 18 and the second electrode fingers 19 are connected to different potentials. Hereafter, the first electrode fingers 18 and the second electrode fingers 19 may be simply referred to as electrode fingers.

When an electrode finger extending direction is defined as a direction in which a plurality of electrode fingers extend, in the present example embodiment, the electrode finger extending direction is orthogonal or substantially orthogonal to an acoustic wave propagation direction. A crossing region A is a region where adjacent electrode fingers overlap when the IDT electrode 7 is seen from a direction orthogonal or substantially orthogonal to the electrode finger extending direction, that is, the acoustic wave propagation direction. An acoustic wave is excited in the crossing region A. In the present example embodiment, the acoustic wave propagation direction is orthogonal or substantially orthogonal to the electrode finger extending direction.

The reflector 8A and the reflector 8B face each other with the IDT electrode 7 therebetween in the direction orthogonal or substantially orthogonal to the electrode finger extending direction. The reflector 8A and the reflector 8B each include a plurality of reflector electrode fingers 8a. A reflector crossing region B of each reflector is a region where adjacent reflector electrode fingers 8a overlap when each reflector is seen from the direction orthogonal or substantially orthogonal to the electrode finger extending direction.

As illustrated in FIG. 2, a first electrode layer 13, a second electrode layer 14A, and a second electrode layer 14B are provided between the support substrate 3 and the piezoelectric layer 6. To be specific, the first electrode layer 13, the second electrode layer 14A, and the second electrode layer 14B are provided on the intermediate layer 4 side of the dielectric layer 5. The first electrode layer 13 and each second electrode layer are embedded in the second layer 4B of the intermediate layer 4. Thus, a portion of the intermediate layer 4 is positioned between the support substrate 3 and both the first electrode layer 13 and each second electrode layer.

In the present example embodiment, the intermediate layer 4 and the dielectric layer 5 are provided between the support substrate 3 and the piezoelectric layer 6. Thus, it is possible to increase the closeness of contact between the support substrate 3 and the piezoelectric layer 6. However, the dielectric layer 5 may be omitted, and the support substrate 3 and the piezoelectric layer 6 may be joined by the intermediate layer 4. In this case, the first electrode layer 13, the second electrode layer 14A, and the second electrode layer 14B may be provided directly on the second main surface 6b of the piezoelectric layer 6. Alternatively, the support substrate 3 and the piezoelectric layer 6 may be joined directly.

As illustrated in FIG. 1, the first electrode layer 13 overlaps the crossing region A of the IDT electrode 7 in plan view. The second electrode layer 14A, which is one of the two second electrode layers, overlaps the reflector crossing region B of the reflector 8A in plan view. The second electrode layers 14B, which is the other second electrode layer, overlaps the reflector crossing region B of the reflector 8B in plan view. In the present specification, “plan view” refers to a view of an acoustic wave device seen from the upward direction in FIG. 2. In FIG. 2, for example, the piezoelectric layer 6 side is the upper side, among the piezoelectric layer 6 side and the support substrate 3 side.

The first electrode layer 13, the second electrode layer 14A, and the second electrode layer 14B are floating electrodes. The term “floating electrode” refers to an electrode that is not electrically connected to either of a signal potential and a reference potential. The first electrode layer 13 and each second electrode layer may be connected to a reference potential. It is sufficient that the first electrode layer 13 and each second electrode layer are not connected to a signal potential.

As illustrated in FIG. 1, the first electrode layer 13 includes a plurality of through-holes 13a and a plurality of cutout portions 13b. In the present specification, the expression “a through-hole is provided in an electrode layer” means that the entirety or substantially the entirety of a portion where the electrode layer is not provided is surrounded by a portion where the electrode layer is provided. That is, the through-hole is not positioned at an outer peripheral edge of the electrode layer. The expression “a cutout portion is provided in an electrode layer” means that a portion where the electrode layer is not provided includes a portion that is not surrounded by a portion where the electrode layer is provided. That is, the cutout portion is positioned on an outer peripheral edge of the electrode layer. In the present specification, “outer peripheral edge” refers to an outer peripheral edge when seen in plan view.

As with the first electrode layer 13, the second electrode layer 14A and the second electrode layer 14B each include a plurality of through-holes 14a and a plurality of cutout portions 14b. However, the configuration of the second electrode layer 14A and the second electrode layer 14B is not particularly limited. The second electrode layer 14A and the second electrode layer 14B may be omitted.

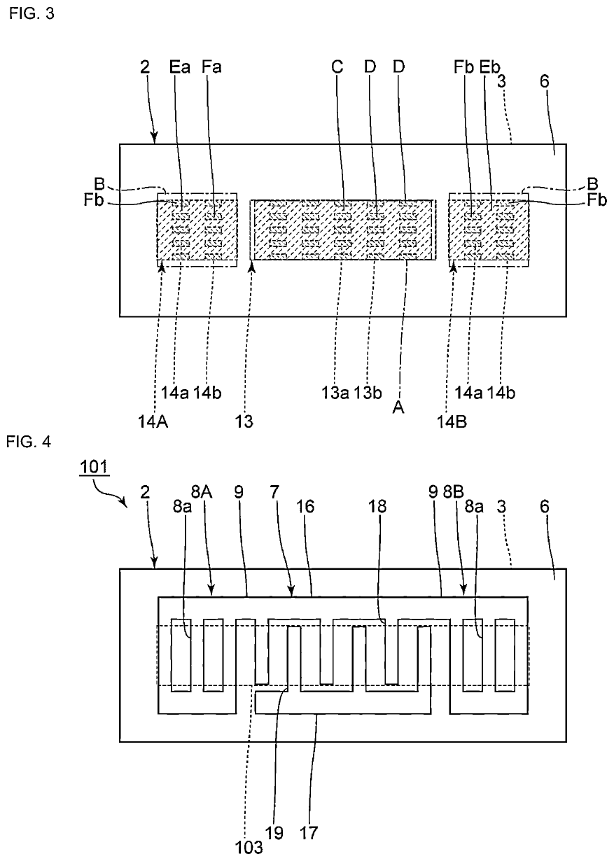

FIG. 3 is a schematic plan view illustrating each region in the first example embodiment.

The piezoelectric substrate 2 includes a first formation region C and a first non-formation region D. To be specific, the first formation region C is a region that overlaps the crossing region A and overlaps the first electrode layer 13 in plan view. That is, the first formation region C is a region of the piezoelectric substrate 2 that overlaps in plan view a portion where the first electrode layer 13 is provided. The first non-formation region D is a region that overlaps the crossing region A and does not overlap the first electrode layer 13 in plan view. That is, the first non-formation region D is a region of the piezoelectric substrate 2 that overlaps in plan view a portion where the first electrode layer 13 is not provided. The piezoelectric substrate 2 of the acoustic wave device 1 includes a plurality of first non-formation regions D. To be more specific, some first non-formation regions D among all of the first non-formation regions D are regions of the piezoelectric substrate 2 each of which overlaps a corresponding one of the through-holes 13a in plan view. The other first non-formation regions D are regions of the piezoelectric substrate 2 each of which overlaps a corresponding one of the cutout portions 13b in plan view.

A feature of the present example embodiment is that the piezoelectric substrate 2 includes the first formation region C and the first non-formation region D, and the first non-formation region D overlaps in plan view at least one of the portions between adjacent electrode fingers. Thus, the acoustic wave device 1 can be identified if the acoustic wave device 1 includes a piezoelectric substrate 2 with a defect. Thus, it is possible to reduce or prevent the occurrence of a fault in a product including an acoustic wave device 1. The details of this will be described below by comparing the present example embodiment with a comparative example. Hereafter, unless otherwise noted, “a portion between electrode fingers” refers to a portion between adjacent electrode fingers.

As illustrated in FIG. 4, the comparative example differs from the first example embodiment in that an electrode layer 103 does not include a through-hole and a cutout portion and that the electrode layer 103 overlaps the IDT electrode 7 and a pair of reflectors in plan view.

As described above, the acoustic wave device 1 according to the first example embodiment illustrated in FIG. 2 is used, for example, in a band-pass filter, a multiplexer, a high-frequency front-end circuit, or the like. Therefore, the above products, each including the acoustic wave device 1, are manufactured with processes after a process of manufacturing the acoustic wave device 1.

Here, in the process of manufacturing the acoustic wave device 1, a defect may occur on the support substrate 3 side of the piezoelectric substrate 2. When the support substrate 3, the intermediate layer 4, and the dielectric layer 5 are the layers of the piezoelectric substrate 2, examples of the defect include delamination between any of the layers, entry of a foreign substance into a space between any of the layers, and the occurrence of a flaw in any of the layers.

The same applies to an acoustic wave device 101 according to the comparative example illustrated in FIG. 4. However, in the acoustic wave device 101 according to the comparative example, a region where the electrode layer 103 is provided overlaps the crossing region when seen in plan view. Light such as visible light used to observe does not easily pass through the electrode layer 103, which is made of a metal. Therefore, it is difficult to identify a defect on the support substrate 3 side when the piezoelectric substrate 2 is seen from the piezoelectric layer 6 side. Thus, it is difficult to sort out an acoustic wave device 101 including a defect in the piezoelectric substrate 2. As a result, for example, a fault related to reliability may occur easily in a product including an acoustic wave device 101. That is, yield may decrease.

In contrast, in the first example embodiment illustrated in FIG. 2, the piezoelectric substrate 2 includes the first non-formation region D, which overlaps in plan view a portion where the first electrode layer 13 is not provided. Moreover, the first non-formation region D overlaps in plan view at least one of the portions between electrode fingers. Here, the piezoelectric layer 6, the dielectric layer 5, and the intermediate layer 4 are each made of, for example, a piezoelectric material or a dielectric and each have a small thickness. Therefore, light such as visible light used to observe sufficiently passes through the piezoelectric layer 6, the dielectric layer 5, and the intermediate layer 4. Thus, it is possible to easily observe the support substrate 3 side from a portion where the first non-formation region D overlaps in plan view a portion between electrode fingers. Thus, it is possible to identify an acoustic wave device 1 including a defect in the piezoelectric substrate 2. Thus, it is possible to reduce or prevent the occurrence of a fault in a product including an acoustic wave device 1. Accordingly, it is possible to increase the yield of the product, and it is possible to increase production efficiency.

As described above, an acoustic wave is excited in the crossing region A. Therefore, if a defect that affects the crossing region A occurs, the electric characteristics of the acoustic wave device 1 tend to become unstable. On the other hand, the first non-formation region D overlaps the crossing region A in plan view. Thus, it is easy to identify an acoustic wave device 1 including a defect that is likely to affect the crossing region A. Accordingly, it is possible to more reliably increase the production efficiency of a product including an acoustic wave device 1.

In addition, the first electrode layer 13 and the IDT electrode 7 face each other with the piezoelectric layer 6 therebetween. Thus, it is possible to increase the electrostatic capacitance of the acoustic wave device 1. Thus, it is possible to reduce the size of the acoustic wave device 1 while obtaining a desirable electrostatic capacitance.

Hereafter, further details of the configuration of the first example embodiment will be described. First, examples of the material of each layer in the piezoelectric substrate 2 will be described. In the present specification, the meaning of an expression “a member is made of a material” includes a meaning that the material includes a very small amount of impurity that does not degrade the electric characteristics of an acoustic wave device. In the present specification, “main component” refers to a component whose content ratio is greater than about 50 wt %. The material of the main component may exist in a single-crystal state, a polycrystal state, an amorphous state, or a state in which these states are mixed.

In the first example embodiment, the support substrate 3 of the piezoelectric substrate 2 is made of silicon, for example. The azimuth angle of the main surface of the support substrate 3 is (111), for example. However, the azimuth angle and the material of the support substrate 3 are not limited to the above. Examples of the material of the support substrate 3 include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, DLC (diamond-like carbon), or diamond; semiconductors such as silicon, or materials including any of the above materials as a main component. The spinel includes an aluminum compound including, for example, one or more elements of Mg, Fe, Zn, Mn, or the like, or oxygen. Examples of the spinel include, for example, MgAl₂O₄, FeAl₂O₄, ZnAl₂O₄, Of MnAl₂O₄.

In the first example embodiment, the first layer 4A of the intermediate layer 4 is a high-acoustic-velocity film as a high-acoustic-velocity material layer. A high-acoustic-velocity material layer is a layer in which the acoustic velocity is relatively high. To be more specific, the acoustic velocity of a bulk wave that propagates in a high-acoustic-velocity material layer is higher than the acoustic velocity of an acoustic wave that propagates in the piezoelectric layer 6. In the first example embodiment, the first layer 4A as a high-acoustic-velocity material layer is made of silicon nitride, for example. The material of a high-acoustic-velocity material layer is not limited to the above. Examples of the material include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, DLC (diamond-like carbon), or diamond, semiconductors such as silicon, and materials including any of the above materials as a main component. The spinel includes, for example, an aluminum compound including one or more elements of Mg, Fe, Zn, Mn, or the like, or oxygen. Examples of the spinel include MgAl₂O₄, FeAl₂O₄, ZnAl₂O₄, or MnAl₂O₄.

In the first example embodiment, the second layer 4B of the intermediate layer 4 is a low-acoustic-velocity film. A low-acoustic-velocity film is a film in which the acoustic velocity is relatively low. To be more specific, the acoustic velocity of a bulk wave that propagates in a low-acoustic-velocity film is lower than the acoustic velocity of a bulk wave that propagates in the piezoelectric layer 6. In the first example embodiment, the second layer 4B as a low-acoustic-velocity film is made of silicon oxide, for example. However, the material of a low-acoustic-velocity film is not limited to the above. Examples of the material include dielectrics such as glass, silicon oxide, silicon oxynitride, lithium tantalum oxide, or chemical compounds in which fluorine, carbon, or boron is added to silicon oxide, or materials including any of the above materials as a main component. In the first example embodiment, the dielectric layer 5 is also a low-acoustic-velocity film the same as or similar to the second layer 4B.

Examples of the material of the piezoelectric layer 6 include lithium niobate, lithium tantalate, zinc oxide, aluminum nitride, quartz, or PZT (lead zirconate titanate). Preferably, the material of the piezoelectric layer 6 is, for example, lithium niobate such as LiNbO₃ or lithium tantalate such as LiTaO₃.

In the piezoelectric substrate 2, the first layer 4A as a high-acoustic-velocity material layer, the second layer 4B and the dielectric layer 5 as low-acoustic-velocity films, and the piezoelectric layer 6 are stacked in this order. Thus, it is possible to effectively confine the energy of an acoustic wave in the piezoelectric layer 6 side.

In the first example embodiment, the first electrode layer 13, the second electrode layer 14A, and the second electrode layer 14B are made of Ti, for example. However, the material the first electrode layer 13 and each second electrode layer is not limited to the above.

The IDT electrode 7, the reflector 8A, and the reflector 8B each include a multilayer metal film. To be specific, in each of the IDT electrode 7, the reflector 8A, and the reflector 8B, for example, a Ti layer, an Al layer, and a Ti layer are stacked in this order. However, the material of each of the IDT electrode 7 and each reflector is not limited to the above. The IDT electrode 7 and each reflector each may include a single-layer metal film.

Hereafter, examples of the design parameters of the acoustic wave device 1 according to the first example embodiment will be described. Here, λ denotes a wavelength that is determined by the electrode finger pitch of the IDT electrode 7. The term “electrode finger pitch” refers to the center-to-center distance between adjacent electrode fingers that are connected to different potentials in the acoustic wave propagation direction. To be specific, λ=2p, where p is the electrode finger pitch.

IDT electrode 7; layer configuration Ti layer/Al layer/Ti layer, total thickness about 0.2λ or less

Piezoelectric Layer 6; material LiNbO₃, thickness about 1λ or less

Dielectric Layer 5; material SiO₂, thickness about 0.2λ or less

First Electrode Layer 13; material Ti, thickness about 0.1λ or less

Second Layer 4B; material SiO₂, thickness about 0.2λ or less

First Layer 4A; material SiN, thickness about 0.5λ or less

Support Substrate 3; material Si, azimuth angle (111)

For example, in the design parameters listed above, the material of the piezoelectric layer 6 may be LiTaO₃. The thickness of each of the second electrode layer 14A and the second electrode layer 14B may be, for example, about 0.1λ or less, as with the first electrode layer 13.

As illustrated in FIG. 3, the piezoelectric substrate 2 includes a second formation region Ea, a second non-formation region Fa, a second formation region Eb, and a second non-formation region Fb. To be specific, the second formation region Ea is a region that overlaps the reflector crossing region B of the reflector 8A and overlaps the second electrode layer 14A in plan view. The second non-formation region Fa is a region that overlaps the reflector crossing region B of the reflector 8A and does not overlap the second electrode layer 14A in plan view. The second formation region Eb is a region that overlaps the reflector crossing region B of the reflector 8B and overlaps the second electrode layer 14B in plan view. The second non-formation region Fb is a region that overlaps the reflector crossing region B of the reflector 8B and does not overlap the second electrode layer 14B in plan view.

The piezoelectric substrate 2 of the acoustic wave device 1 includes a plurality of second non-formation regions Fa. To be more specific, some second non-formation regions Fa among all of the second non-formation regions Fa are regions of the piezoelectric substrate 2 each of which overlaps in plan view a corresponding one of the through-holes 14a provided in the second electrode layer 14A. The other second non-formation regions Fa are regions of the piezoelectric substrate 2 each of which overlaps in plan view a corresponding one of the cutout portions 14b provided in the second electrode layer 14A. Similarly, the piezoelectric substrate 2 includes a plurality of second non-formation regions Fb.

As illustrated in FIG. 2, the plurality of second non-formation regions Fa each overlap in plan view one of the portions between adjacent reflector electrode fingers 8a of the reflector 8A. Similarly, the plurality of second non-formation regions Fb each overlap in plan view one of the portions between adjacent reflector electrode fingers 8a of the reflector 8B. Hereafter, unless otherwise noted, “the portions between the reflector electrode fingers 8a” refer to the portions between adjacent reflector electrode fingers 8a.

In the present example embodiment, the second electrode layer 14A and the reflector 8A face each other with the piezoelectric layer 6 therebetween. Similarly, the second electrode layer 14B and the reflector 8B face each other with the piezoelectric layer 6 therebetween. Thus, it is possible to effectively increase the electrostatic capacitance of the acoustic wave device 1. Thus, it is possible to more reliably reduce the size of the acoustic wave device 1 while obtaining a desirable electrostatic capacitance.

In addition, it is possible to easily observe the support substrate 3 side from a portion where the second non-formation region Fa overlaps in plan view a portion of the reflector 8A between the reflector electrode fingers 8a. Similarly, it is possible to easily observe the support substrate 3 side from a portion where the second non-formation region Fb overlaps in plan view a portion of the reflector 8B between the reflector electrode fingers 8a. Thus, it is possible to more reliably identify an acoustic wave device 1 including a defect in the piezoelectric substrate 2. Thus, it is possible to more reliably reduce or prevent the occurrence of a fault in a product including an acoustic wave device 1.

As illustrated in FIG. 1, in the present example embodiment, the IDT electrode 7 and each reflector are connected. To be specific, the first busbar 16 and the reflector 8A are connected by a connection wiring line 9. The first busbar 16 and the reflector 8B are connected by another connection wiring line 9. To be more specific, the first busbar 16, each connection wiring line 9, and each reflector are integrally provided. The first busbar 16, each reflector, and each connection wiring line 9 may be independently provided from different materials, and the first busbar 16 and each reflector may be connected by a corresponding connection wiring line 9. Alternatively, the first busbar 16 and each reflector need not be connected.

Hereafter, preferable configurations s in the first example embodiment will be described. It is preferable that the piezoelectric substrate 2 includes a plurality of first non-formation regions D. Thus, it is possible to easily observe the support substrate 3 side.

It is more preferable that at least some first non-formation regions D among all of the first non-formation regions D are arranged at a period that is an integer multiple of the electrode finger pitch of the IDT electrode 7 in the direction orthogonal or substantially orthogonal to the electrode finger extending direction. In the first example embodiment, the plurality of through-holes 13a provided in the first electrode layer 13 are arranged at a period that is an integer multiple of the electrode finger pitch of the IDT electrode 7 in the direction orthogonal to the electrode finger extending direction. The plurality of cutout portions 13b provided in the first electrode layer 13 are also arranged at a period that is an integer multiple of the electrode finger pitch of the IDT electrode 7 in the direction orthogonal to the electrode finger extending direction. Thus, the plurality of first non-formation regions D are disposed as described above.

In this case, at least some portions between electrode fingers among all of the portions between electrode fingers each overlap a corresponding one of the first non-formation regions D in plan view. Thus, it is easy to observe the support substrate 3 side. In addition, the first electrode layer 13 has a periodic structure that matches the IDT electrode 7. Thus, it is possible to improve the resonance characteristics of the acoustic wave device 1. To be specific, for example, it is possible to increase the Q-value.

It is preferable that all of the portions between electrode fingers each overlap a corresponding one of the first non-formation regions D in plan view. It is more preferable that the first non-formation regions D are arranged at a period that is the same or substantially the same as the electrode finger pitch of the IDT electrode 7 in the direction orthogonal or substantially orthogonal to the electrode finger extending direction. In this case, it is possible to more easily observe the support substrate 3 side, and it is possible to improve the resonance characteristics of the acoustic wave device 1.

Here, the “width” of each of the through-hole 13a and the cutout portion 13b, provided in the first electrode layer 13, and a portion between electrode fingers of the IDT electrode 7 is defined as the dimension thereof in the direction orthogonal or substantially orthogonal to the electrode finger extending direction. It is preferable that the dimension, in the direction orthogonal or substantially orthogonal to the electrode finger extending direction, of a portion where the first non-formation region D illustrated in FIG. 2 and a portion between electrode fingers overlap in plan view is about 0.8 times or greater and about 1 time or less of the width of the portion between electrode fingers. It is preferable that the width of each of the through-hole 13a and the cutout portion 13b provided in the first electrode layer 13 is about 0.8 times or greater and about 1 time or less of the width of a portion between electrode fingers. Thus, it is possible to easily observe the support substrate 3 side.

It is preferable that all of the first non-formation regions D of the piezoelectric substrate 2 are regions that overlap in plan view the through-holes 13a or the cutout portions 13b provided in the same first electrode layer 13. In this case, it is sufficient that the acoustic wave device 1 includes only one first electrode layer 13 that overlaps the first formation region C of the piezoelectric substrate 2. Thus, it is possible to more reliably stabilize the potential of the first electrode layer 13 that overlaps the IDT electrode 7 in plan view. Thus, it is possible to improve the resonance characteristics of the acoustic wave device 1.

As illustrated in FIG. 3, it is preferable that the piezoelectric substrate 2 includes a plurality of first non-formation regions D in the electrode finger extending direction. In the first example embodiment, a plurality of through-holes 13a and two cutout portions 13b are provided in the first electrode layer 13 so as to be arranged in the electrode finger extending direction. Thus, the plurality of first non-formation regions D are arranged as described above. Thus, it is possible to observe the support substrate 3 side in a wide range, and it is possible to increase the strength of the first electrode layer 13.

To be more specific, in the first example embodiment, a through-hole 13a and a cutout portion 13b are not provided in a portion of the first electrode layer 13 that overlaps each electrode finger in plan view. On the other hand, a plurality of through-holes 13a and two cutout portions 13b are provided in a portion of the first electrode layer 13 that overlaps in plan view a portion between electrode fingers. The first electrode layer 13 is provided between the plurality of through-holes 13a and between a through-hole 13a and a cutout portion 13b. Thus, the first electrode layer 13 has a structure such that portions that overlap electrode fingers in plan view are connected by a plurality of connection portions. Thus, it is possible to observe the support substrate 3 side in a wide range, and it is possible to increase the strength of the first electrode layer 13.

Referring back to FIG. 2, it is preferable that the piezoelectric substrate 2 includes a plurality of second non-formation regions Fa and a plurality of second non-formation regions Fb. Thus, it is possible to more easily observe the support substrate 3 side, and it is possible to more reliably identify an acoustic wave device 1 including a defect in the piezoelectric substrate 2. However, the piezoelectric substrate 2 may include one second non-formation region Fa and may include one second non-formation region Fb.

It is preferable that at least some second non-formation regions Fa among all of the second non-formation regions Fa are arranged at a period that is an integer multiple of the reflector electrode finger pitch of the reflector 8A in the direction orthogonal or substantially orthogonal to the electrode finger extending direction. In the first example embodiment, the plurality of through-holes 14a provided in the second electrode layer 14A are arranged at a period that is an integer multiple of the reflector electrode finger pitch of the reflector 8A in the direction orthogonal or substantially orthogonal to the electrode finger extending direction. The plurality of cutout portions 14b provided in the second electrode layer 14A are also arranged at a period that is an integer multiple of the reflector electrode finger pitch of the reflector 8A in the direction orthogonal or substantially orthogonal to the electrode finger extending direction. Thus, the plurality of second non-formation regions Fa are disposed as described above. The term “reflector electrode finger pitch” refers to the center-to-center distance between adjacent reflector electrode fingers 8a in the acoustic wave propagation direction.

In the first example embodiment, the reflector 8B is configured in the same or similar way to the reflector 8A. The second electrode layer 14B is configured in the same or similar way to the second electrode layer 14A. The second non-formation regions Fb of the piezoelectric substrate 2 are configured in the same or similar way to the second non-formation regions Fa. Thus, at least some second non-formation regions Fb among all of the second non-formation regions Fb are arranged at a period that is an integer multiple of the reflector electrode finger pitch of the reflector 8B in the direction orthogonal or substantially orthogonal to the electrode finger extending direction.

At least some portions of the reflector 8A between the reflector electrode fingers 8a among all of the portions between the reflector electrode fingers 8a each overlap a corresponding one of the second non-formation regions Fa in plan view. The relationship between portions of the reflector 8B between the reflector electrode fingers 8a and the second non-formation regions Fb is the same as or similar to the above. Thus, it is easy to observe the support substrate 3 side.

The periodic structure of the reflector 8A and the reflector 8B matches the periodic structure of the IDT electrode 7. Thus, the second electrode layer 14A and the second electrode layer 14B have a periodic structure that matches the IDT electrode 7, the reflector 8A, and the reflector 8B. Thus, it is possible to effectively improve the resonance characteristics of the acoustic wave device 1. To be specific, for example, it is possible to effectively increase the Q-value.

It is preferable that all of the portions of the reflector 8A between the reflector electrode fingers 8a each overlap a corresponding one of the second non-formation regions Fa in plan view. Similarly, it is preferable that all of the portions of the reflector 8B between the reflector electrode fingers 8a each overlap a corresponding one of the second non-formation regions Fb in plan view. In these cases, it is possible to more easily observe the support substrate 3 side, and it is possible to effectively improve the resonance characteristics of the acoustic wave device 1.

It is preferable that the first electrode layer 13 is not connected to the second electrode layer 14A and the second electrode layer 14B. In this case, a residue of a resist is not easily generated when the first electrode layer 13, the second electrode layer 14A, and the second electrode layer 14B are formed by a lift-off process, for example.

To be specific, to form the first electrode layer 13, the second electrode layer 14A, and the second electrode layer 14B by a lift-off process, a resist pattern is provided on a surface on which the first electrode layer 13, the second electrode layer 14A, and the second electrode layer 14B are to be formed. The resist pattern has been patterned by removing a portion of a resist. To be more specific, the resist has been removed from portions of the resist pattern corresponding to the shapes of the first electrode layer 13, the second electrode layer 14A, and the second electrode layer 14B. Next, an electrode layer is provided on the resist pattern. At this time, the electrode layer includes a portion provided on the resist and a portion provided on the portions from which the resist has been removed. Next, the resist pattern is peeled off. Through the above process, it is possible to form the first electrode layer 13, the second electrode layer 14A, and the second electrode layer 14B.

In the first example embodiment, the first electrode layer 13 is not connected to the second electrode layer 14A and the second electrode layer 14B. Thus, the resist extends continuously in a portion of the resist pattern corresponding to a region between the first electrode layer 13 and the second electrode layer 14A. Similarly, the resist extends continuously in a portion of the resist pattern corresponding to a region between the first electrode layer 13 and the second electrode layer 14B. Thus, the resist pattern can be easily peeled off, and a resist residue is not easily generated.

As illustrated in FIG. 2, it is preferable that the piezoelectric substrate 2 includes the dielectric layer 5. The dielectric layer 5 is provided between the piezoelectric layer 6 and the first electrode layer 13. Therefore, the IDT electrode 7 and the first electrode layer 13 face each other with the piezoelectric layer 6 and the dielectric layer 5 therebetween. Thus, electrostatic capacitance is provided. It is possible to easily adjust the magnitude of the electrostatic capacitance by adjusting the thickness of the dielectric layer 5. Thus, it is possible to easily adjust the band width ratio.

It is preferable that the intermediate layer 4 includes a layer made of silicon oxide, for example. In the first example embodiment, the second layer 4B is a layer made of silicon oxide, for example. Thus, it is possible to reduce the temperature coefficient of frequency (TCF) of the acoustic wave device 1. Thus, it is possible to improve the frequency temperature characteristics of the acoustic wave device 1.

In the first example embodiment, an example in which the shape of the first non-formation region D in plan view is a rectangle or substantially a rectangle has been described. However, the shape of the first non-formation region D in plan view is not limited to the above. The shape of the first non-formation region D in plan view may be, for example, a circle, an ellipse, a triangle, or a polygon other than a rectangle.

As illustrated in FIG. 1, in the first example embodiment, the first electrode layer 13 does not overlap the first busbar 16 and the second busbar 17 of the IDT electrode 7 in plan view. However, the first electrode layer 13 may overlap the first busbar 16 or the second busbar 17 in plan view.

As illustrated in FIG. 2, the cross-sectional shape of each electrode finger of the IDT electrode 7 is a trapezoid or substantially a trapezoid. To be specific, each electrode finger includes a first surface 7a, a second surface 7b, and a side surface 7c. The first surface 7a and the second surface 7b face each other in the thickness direction of the electrode finger. The side surface 7c is connected to the first surface 7a and the second surface 7b. The side surface 7c extends at an angle to the normal direction of the first main surface 6a of the piezoelectric layer 6. However, the side surface 7c of each electrode finger may extend parallel or substantially parallel to the normal direction of the first main surface 6a of the piezoelectric layer 6.

As illustrated in FIG. 1, in the first example embodiment, the entirety or substantially the entirety of each through-hole 13a and each cutout portion 13b of the first electrode layer 13 overlaps in plan view a portion between electrode fingers of the IDT electrode 7. Therefore, the entirety or substantially the entirety of each first non-formation region overlaps in plan view a portion between electrode fingers. Similarly, the entirety or substantially the entirety of each through-hole 14a and each cutout portion 14b of the second electrode layer 14A and the second electrode layer 14B also overlaps in plan view a portion between the reflector electrode fingers 8a. Therefore, the entirety or substantially the entirety of each second non-formation region overlaps in plan view a portion between the reflector electrode fingers 8a.

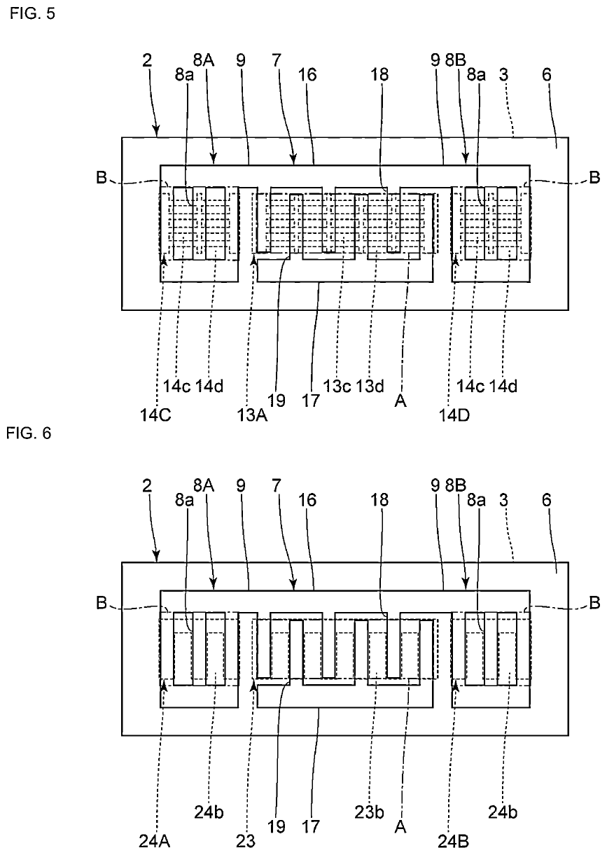

However, the disposition of each through-hole 13a and each cutout portion 13b of the first electrode layer 13 and each through-hole 14a and each cutout portion 14b of the second electrode layer 14A and the second electrode layer 14B is not limited to the above. For example, in a modification of the first example embodiment illustrated in FIG. 5, a portion of each through-hole 13c and each cutout portion 13d of the first electrode layer 13A overlaps the electrode finger of the IDT electrode 7 in plan view. Another portion of each through-hole 13c and each cutout portion 13d overlaps in plan view a portion between electrode fingers. To be specific, both end portions of each through-hole 13c and each cutout portion 13d in the direction parallel or substantially parallel to the acoustic wave propagation direction overlap electrode fingers in plan view. Therefore, a portion of each first non-formation region overlaps the electrode fingers in plan view.

Similarly, a portion of each through-hole 14c and each cutout portion 14d of a second electrode layer 14C and a second electrode layer 14D overlaps the reflector electrode finger 8a in plan view. Another portion of each through-hole 14c and each cutout portion 14d overlaps a portion between the reflector electrode fingers 8a. To be specific, both end portions of each through-hole 14c and each cutout portion 14d in the direction parallel or substantially parallel to the acoustic wave propagation direction overlap the reflector electrode fingers 8a in plan view. Therefore, a portion of each second non-formation region overlaps the reflector electrode fingers 8a in plan view.

Also with the present modification, as with the first example embodiment, it is possible to identify an acoustic wave device including a piezoelectric substrate 2 including a defect, and it is possible to reduce or prevent the occurrence of a fault in a product including an acoustic wave device. In addition, as with the first example embodiment, it is also possible to increase the electrostatic capacitance of an acoustic wave device. The configuration of the first electrode layer 13A may be a configuration such that a portion of at least one through-hole 13c or at least one cutout portion 13d overlaps an electrode finger of the IDT electrode 7. Thus, the configuration of regions in the piezoelectric substrate 2 may be a configuration such that at least one first non-formation region overlaps an electrode finger in plan view. The configuration of the second electrode layer 14C may be a configuration such that a portion of at least one through-hole 14c or at least one cutout portion 14d overlaps the reflector electrode finger 8a. Thus, the configuration of regions in the piezoelectric substrate 2 may be a configuration such that at least one second non-formation region overlaps the reflector electrode finger 8a in plan view. The same applies to the second electrode layer 14D.

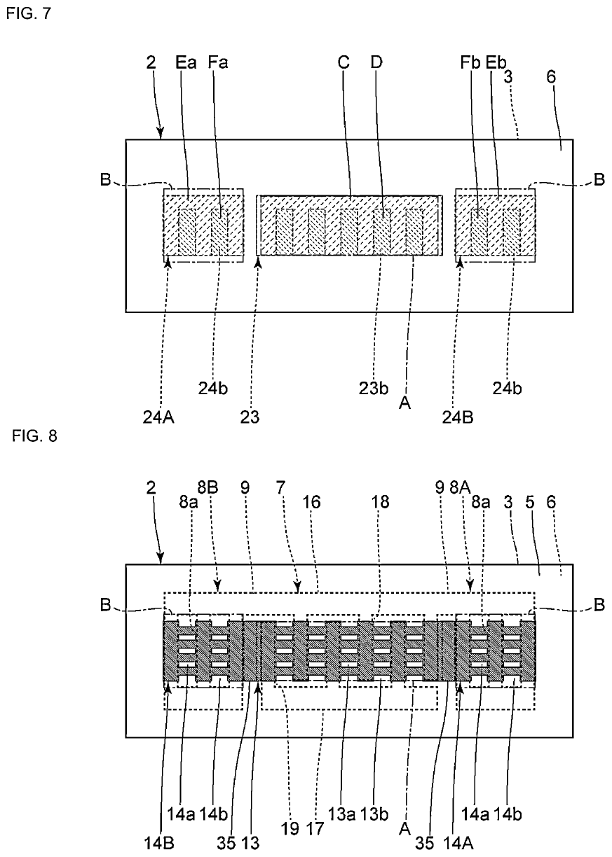

FIG. 6 is a schematic plan view of an acoustic wave device according to a second example embodiment of the present invention. FIG. 7 is a schematic plan view illustrating each region in the second example embodiment.

As illustrated in FIG. 6, the present example embodiment differs from the first example embodiment in the configuration of a first electrode layer 23, a second electrode layer 24A, and a second electrode layer 24B. Thus, the present example embodiment differs from the first example embodiment also in regions of the piezoelectric substrate 2. In other respects, the acoustic wave device according to the present example embodiment has a configuration the same as or similar to that of the acoustic wave device 1 according to the first example embodiment.

The first electrode layer 23 does not include a through-hole. On the other hand, the first electrode layer 23 includes a plurality of cutout portions 23b. The plurality of cutout portions 23b are arranged in the direction orthogonal or substantially orthogonal to the electrode finger extending direction. To be specific, in the present example embodiment, the plurality of cutout portions 23b are arranged at a period that is the same or substantially the same as the electrode finger pitch. Only one cutout portion 23b is provided in the electrode finger extending direction.

Thus, as illustrated in FIG. 7, the piezoelectric substrate 2 includes only one first non-formation region D in the electrode finger extending direction. The piezoelectric substrate 2 includes a plurality of first non-formation regions D in the direction orthogonal or substantially orthogonal to the electrode finger extending direction. To be more specific, the plurality of first non-formation regions D are arranged at a period that is the same or substantially the same as the electrode finger pitch in the direction orthogonal or substantially the same to the electrode finger extending direction.

The cutout portion 23b provided in the first electrode layer 23 has a slit shape, for example. To be more specific, the cutout portion 23b extends in the electrode finger extending direction. In the present example embodiment, the dimension of the cutout portion 23b in the electrode finger extending direction is, for example, about 0.5 times or greater and about 0.8 times or less of the dimension of the crossing region A in the electrode finger extending direction. Thus, the dimension of each first non-formation region D of the piezoelectric substrate 2 in the electrode finger extending direction is, for example, about 0.5 times or greater and about 0.8 times or less of the dimension of the crossing region A in the electrode finger extending direction. In this case, it is easy to observe the support substrate 3 side, and it is possible to make the strength of the first electrode layer 23 sufficiently high. However, the dimension of the cutout portion 23b and the first non-formation region D in the electrode finger extending direction may be less than, for example 0.5 times the dimension of the crossing region A in the electrode finger extending direction.

Similarly, the second electrode layer 24A and the second electrode layer 24B do not include a through-hole and each include a plurality of cutout portions 24b. Each cutout portion 24b has a slit shape, for example. The plurality of cutout portions 24b are arranged in the direction orthogonal or substantially orthogonal to the electrode finger extending direction. To be specific, the plurality of cutout portions 24b are arranged at a period that is the same or substantially the same as the electrode finger pitch. Only one cutout portion 24b is provided in the electrode finger extending direction.

Thus, the piezoelectric substrate 2 includes only one second non-formation region Fa in the electrode finger extending direction. The piezoelectric substrate 2 includes a plurality of second non-formation regions Fa in the direction orthogonal or substantially orthogonal to the electrode finger extending direction. To be more specific, the plurality of second non-formation regions Fa are arranged at a period that is the same or substantially the same as the reflector electrode finger pitch in the direction orthogonal or substantially orthogonal to the electrode finger extending direction. A plurality of second non-formation regions Fb are disposed in the same or similar way to the plurality of second non-formation regions Fa.

Also with the present example embodiment, as with the first example embodiment, it is possible to identify an acoustic wave device including a piezoelectric substrate 2 including a defect, and it is possible to reduce or present the occurrence of a fault in a product including an acoustic wave device. In addition, as with the first example embodiment, it is also possible to increase the electrostatic capacitance of an acoustic wave device.

In the present example embodiment, an example in which the shape of the cutout portion 23b is a slit shape has been described. The cutout portion 23b need not be provided in the first electrode layer 23, and only one through-hole may be provided in the electrode finger extending direction. In this case, the through-hole may have a slit shape, for example.

FIG. 8 is a schematic bottom view illustrating the configuration of a first electrode layer and a second electrode layer in a third example embodiment of the present invention. FIG. 8 illustrates the electrode configuration of the dielectric layer 5 as seen from a direction corresponding to the downward direction in FIG. 2. Therefore, FIG. 8 is left-right reversed compared with schematic plan views such as FIG. 1. The same applies to schematic bottom views other than FIG. 8.

The present example embodiment differs from the first example embodiment in that the first electrode layer 13, the second electrode layer 14A, and the second electrode layer 14B are connected. In other respects, an acoustic wave device according to the present example embodiment has a configuration the same as or similar to that of the acoustic wave device 1 according to the first example embodiment.

The first electrode layer 13 and the second electrode layer 14A are connected by a connection electrode 35. Similarly, the first electrode layer 13 and the second electrode layer 14B are connected by another connection electrode 35. The first electrode layer 13, each connection electrode 35, and each second electrode layer are integrally provided. In FIG. 8, the boundaries between the first electrode layer 13, each second electrode layer, and each connection electrode 35 are shown by two-dot chain lines. However, for example, the first electrode layer 13, each second electrode layer, and each connection electrode 35 may be independently provided from different materials, and the first electrode layer 13 and each second electrode layer may be connected by each connection electrode 35.

Also with the present example embodiment, as with the first example embodiment, it is possible to identify an acoustic wave device including a piezoelectric substrate 2 including a defect, and it is possible to reduce or prevent the occurrence of a fault in a product including an acoustic wave device. In addition, as with the first example embodiment, it is also possible to increase the electrostatic capacitance of an acoustic wave device.

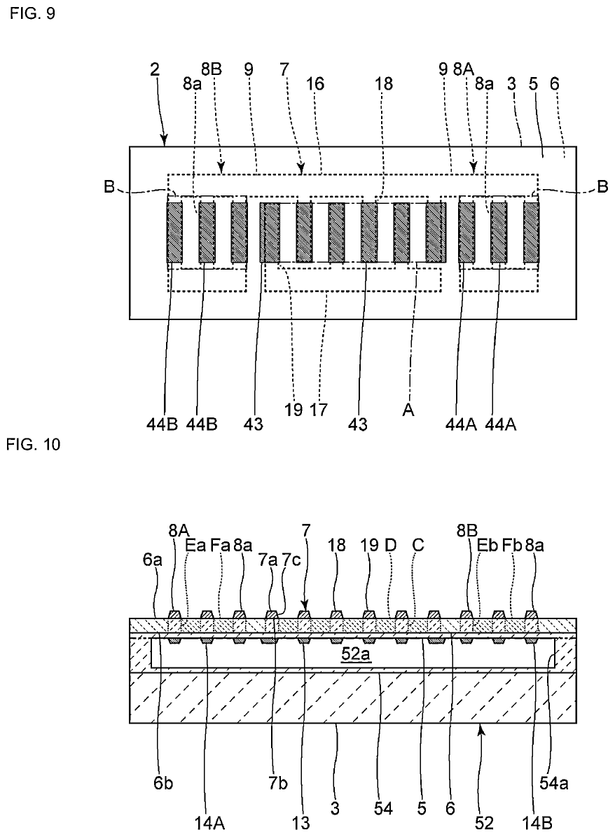

FIG. 9 is a schematic bottom view illustrating the configuration of a first electrode layer and a second electrode layer in a fourth example embodiment of the present invention.

The present example embodiment differs from the first example embodiment in that a plurality of first electrode layers 43, a plurality of second electrode layers 44A, and a plurality of second electrode layers 44B are provided. In other respects, an acoustic wave device according to the present example embodiment has a configuration the same as or similar to that of the acoustic wave device 1 according to the first example embodiment.

The plurality of first electrode layers 43 extend in the electrode finger extending direction, as with a plurality of electrode fingers of the IDT electrode 7. The plurality of first electrode layers 43 are arranged in the direction orthogonal or substantially orthogonal to the electrode finger extending direction, as with the plurality of electrode fingers.

The plurality of first electrode layers 43 overlap the plurality of electrode fingers of the IDT electrode 7 in plan view. On the other hand, the plurality of first electrode layers 43 do not overlap the portions between electrode fingers in plan view. Thus, in the piezoelectric substrate 2, a plurality of first non-formation regions are provided. That is, in the present example embodiment, each first non-formation region is a region of the piezoelectric substrate 2 that overlaps in plan view a portion between the first electrode layers 43 that are adjacent to each other. The plurality of first non-formation regions each overlap in plan view a portion between electrode fingers.

The plurality of second electrode layers 44A overlap the plurality of reflector electrode fingers 8a of the reflector 8A in plan view. On the other hand, the plurality of second electrode layers 44A do not overlap in plan view the portions between the reflector electrode fingers 8a of the reflector 8Aw. Thus, in the piezoelectric substrate 2, a plurality of second non-formation regions are provided. These second non-formation regions are regions of the piezoelectric substrate 2 that overlap in plan view the portions between adjacent second electrode layers 44A. The plurality of second non-formation regions each overlap in plan view a corresponding one of the portions between the reflector electrode fingers 8a of the reflector 8A.

Similarly, the plurality of second electrode layers 44B overlap the plurality of reflector electrode fingers 8a of the reflector 8B in plan view. On the other hand, the plurality of second electrode layers 44B do not overlap in plan view the portions between the reflector electrode fingers 8a of the reflector 8B. Thus, in the piezoelectric substrate 2, a plurality of second non-formation regions are provided. These second non-formation regions are regions of the piezoelectric substrate 2 that overlap in plan view the portions between adjacent second electrode layers 44B. The plurality of second non-formation regions each overlap a corresponding one of the portions between the reflector electrode fingers 8a of the reflector 8B in plan view.

Also with the present example embodiment, as with the first example embodiment, it is possible to identify an acoustic wave device including a piezoelectric substrate 2 including a defect, and it is possible to reduce or prevent the occurrence of a fault in a product including an acoustic wave device. In addition, as with the first example embodiment, it is also possible to increase the electrostatic capacitance of an acoustic wave device.

FIG. 10 is a schematic front sectional view of an acoustic wave device according to a fifth example embodiment of the present invention.

The present example embodiment differs from the first example embodiment in the configuration of a piezoelectric substrate 52. In other respects, the acoustic wave device according to the present example embodiment has a configuration the same as or similar to that of the acoustic wave device 1 according to the first example embodiment.

The piezoelectric substrate 52 includes the support substrate 3, an intermediate layer 54, the dielectric layer 5, and the piezoelectric layer 6. A hollow portion 52a is provided in the piezoelectric substrate 52. To be specific, the intermediate layer 54 includes a recessed portion 54a. The dielectric layer 5 is provided on the intermediate layer 54 so as to cover the recessed portion 54a. Thus, the hollow portion 52a is provided. In the hollow portion 52a, the first electrode layer 13, the second electrode layer 14A, and the second electrode layer 14B are provided.

The intermediate layer 54 includes a side wall portion, facing the recessed portion 54a, and a bottom portion. The side wall portion of the intermediate layer 54 is joined to the dielectric layer 5. The bottom portion of the intermediate layer 54 is joined to the support substrate 3. The bottom portion of the intermediate layer 54 is positioned between the first electrode layer 13, the second electrode layer 14A, the second electrode layer 14B, and the support substrate 3.

It is possible to increase the closeness of contact between the support substrate 3 and the piezoelectric layer 6, because the intermediate layer 54 and the dielectric layer 5 are provided between the support substrate 3 and the piezoelectric layer 6. Moreover, it is possible to effectively confine the energy of an acoustic wave in the piezoelectric layer 6 side, because the hollow portion 52a is provided in the piezoelectric substrate 52. For example, a recessed portion may be provided in the support substrate 3, and the piezoelectric layer 6 may be provided directly on the support substrate 3 so as to cover the recessed portion of the support substrate 3.

Also with the present example embodiment, as with the first example embodiment, it is possible to identify an acoustic wave device including a piezoelectric substrate 52 including a defect, and it is possible to reduce or prevent the occurrence of a fault in a product including an acoustic wave device. In addition, as with the first example embodiment, it is also possible to increase the electrostatic capacitance of an acoustic wave device.

It is possible to use acoustic wave devices according to example embodiments of the present invention in, for example, a filter device. This example will be described below.

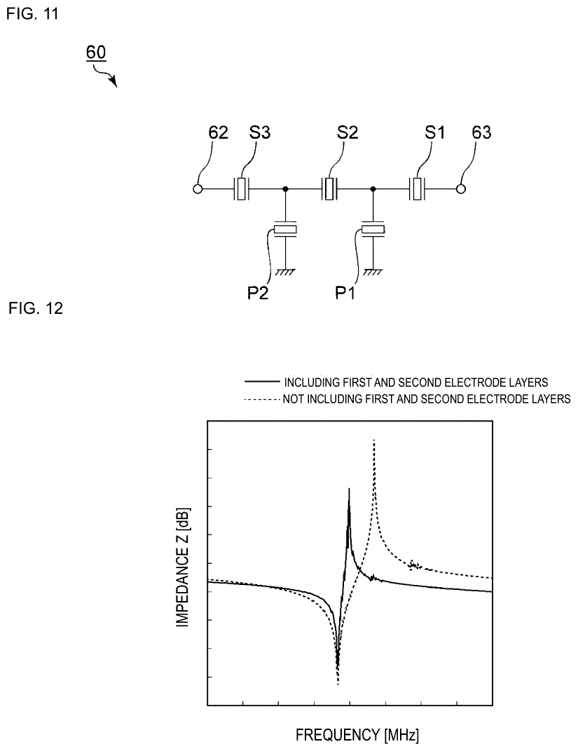

FIG. 11 is a circuit diagram of a filter device according to a sixth example embodiment of the present invention.

A filter device 60 is a ladder filter, for example. The filter device 60 includes a first signal terminal 62, a second signal terminal 63, a plurality of serial-arm resonators, and a plurality of parallel-arm resonators. In the present example embodiment, all of the serial-arm resonators and all of the parallel-arm resonators are acoustic wave resonators. One of the serial-arm resonators and one of the parallel-arm resonators are acoustic wave devices according to example embodiments of the present invention. The other serial-arm resonators and the other parallel-arm resonators are not acoustic wave devices according to example embodiments of the present invention. To be more specific, the other serial-arm resonators and the other parallel-arm resonators do not include a first electrode layer and a second electrode layer according to an example embodiment of the present invention.

However, it is sufficient that at least one of the serial-arm resonators or at least one of the parallel-arm resonators of the filter device 60 is an acoustic wave device according to an example embodiment the present invention. For example, all of the serial-arm resonators and all of the parallel-arm resonators may be acoustic wave devices according to example embodiments of the present invention.

As illustrated in FIG. 11, the first signal terminal 62 and the second signal terminal 63 may be, for example, electrode pads, or may be wiring lines. In the present example embodiment, the first signal terminal 62 is an antenna terminal, for example. The antenna terminal is to be connected to an antenna.

The plurality of serial-arm resonators of the filter device 60 include a serial-arm resonator S1, a serial-arm resonator S2, and a serial-arm resonator S3. The plurality of parallel-arm resonator include a parallel-arm resonator P1 and a parallel-arm resonator P2.

The serial-arm resonator S1, the serial-arm resonator S2, and the serial-arm resonator S3 are serially connected to each other between the first signal terminal 62 and the second signal terminal 63. The parallel-arm resonator P1 is connected between the ground potential and a connection point between the serial-arm resonator S1 and the serial-arm resonator S2. The parallel-arm resonator P2 is connected between the ground potential and a connection point between the serial-arm resonator S2 and the serial-arm resonator S3. In the present example embodiment, the serial-arm resonator S1 and the parallel-arm resonator P1 are acoustic wave devices according to example embodiments of the present invention. However, the arrangement of a serial-arm resonator or a parallel-arm resonator that is an acoustic wave device according to an example embodiment of the present invention is not particularly limited.

The circuit configuration of the filter device 60 is not limited to the above. It is sufficient that the filter device 60 includes at least one serial-arm resonator and at least one parallel-arm resonator. Alternatively, a filter device according to the present invention is not limited to a ladder filter. For example, a filter device may include a longitudinally coupled resonator acoustic wave filter and at least one acoustic wave resonator. In this case, it is sufficient that the at least one acoustic wave resonator is an acoustic wave device according to an example embodiment of the present invention.

The filter device 60 includes an acoustic wave device according to an example embodiment of the present invention. In a process of obtaining the acoustic wave device, it is possible to identify an acoustic wave device if the acoustic wave device includes a defective substrate. Therefore, as an acoustic wave resonator of the filter device 60, it is possible to more reliably use an acoustic wave device that does not include a defect. Thus, it is possible to reduce or prevent the occurrence of a fault in the filter device 60.

As in the present example embodiment, it is preferable that the filter device 60 includes an acoustic wave resonator including a first electrode layer and a second electrode layer according to an example embodiment of the present invention and an acoustic wave resonator not including a first electrode layer and a second electrode layer according to an example embodiment of the present invention. Thus, it is possible to appropriately widen the pass band, and it is possible to improve attenuation characteristics near a frequency at an end portion on the higher side of the pass band or a frequency on the lower side of the pass band. This will be described below.

FIG. 12 illustrates the impedance frequency characteristics of an acoustic wave resonator including a first electrode layer and a second electrode layer and an acoustic wave resonator not including a first electrode layer and a second electrode layer in the sixth example embodiment. In FIG. 12, the resonant frequencies of both of the acoustic wave resonators are adjusted to be the same or substantially the same.

As illustrated in FIG. 12, the difference between the resonant frequency and the anti-resonant frequency of the acoustic wave resonator including a first electrode layer and a second electrode layer is small. Here, the band width ratio of an acoustic wave resonator is represented as (|fr−fa|/fr)×100 [%], where fr is the resonant frequency and fa is the anti-resonant frequency. The value of the band width ratio of the acoustic wave resonator including a first electrode layer and a second electrode layer is small. On the other hand, the value of the band width ratio of the acoustic wave resonator not including a first electrode layer and a second electrode layer is large. In this way, it can be seen that an acoustic wave device according to an example embodiment of the present invention has a relatively small band width ratio.

Thus, by using an acoustic wave device according to an example embodiment of the present invention as a parallel-arm resonator in a filter device, it is possible to improve attenuation characteristics on the lower side of the pass band. To be more specific, it is possible to increase steepness on the lower side of the pass band. In the present specification, “steepness is high” means that a change in frequency relative to a change in attenuation is small near an end portion of the pass band.

Moreover, it is possible to attenuation characteristics on the higher side of the pass band by using an acoustic wave device according to an example embodiment of the present invention as a serial-arm resonator in a filter device. To be more specific, it is possible to increase steepness on the higher side of the pass band.

On the other hand, the band width ratio of the acoustic wave resonator not including a first electrode layer and a second electrode layer is relatively large. Thus, it is possible to easily widen the pass band by using the acoustic wave resonator in a filter device.

Hereafter, the direction orthogonal or substantially orthogonal to the electrode finger extending direction will be referred to as “electrode finger orthogonal direction”. In the first example embodiment described above, as illustrated in FIG. 3, some first non-formation regions D among all of the first non-formation regions D are arranged in the electrode finger extending direction. Some first non-formation regions D among all of the first non-formation regions D are arranged in the electrode finger orthogonal direction. Here, a first imaginary line is defined as an imaginary line that extends in the electrode finger orthogonal direction and passes through a midpoint between the first non-formation regions D that are adjacent to each other in the electrode finger extending direction. In the example schematically illustrated in FIG. 3, four first imaginary lines can be drawn. The first non-formation regions D are not positioned on any of the first imaginary lines.

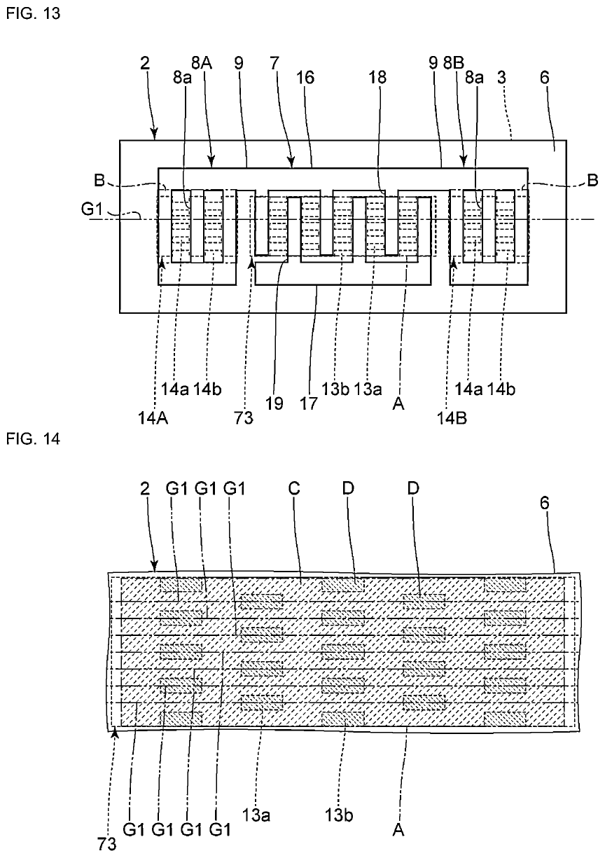

In the above example, the first imaginary line is defined by using the first non-formation regions D. It is possible to define the first imaginary line in the same or similar way by using the through-holes 13a and the cutout portions 13b of the first electrode layer 13 illustrated in FIG. 1 when seen in plan view. Thus, the first imaginary line will be used in the same or similar way in describing the disposition of the first non-formation regions D, the through-holes 13a, and the cutout portions 13b. FIG. 13 is a schematic plan view of an acoustic wave device according to a seventh example embodiment of the present invention. FIG. 14 is a schematic plan view illustrating each region near a portion overlapping a first electrode layer in plan view and first imaginary lines in the seventh example embodiment. In FIG. 13, only one first imaginary line G1 among a plurality of first imaginary lines G1 is drawn.

As illustrated in FIG. 13, the present example embodiment differs from the fifth example embodiment illustrated in FIG. 10 in the configuration of a first electrode layer 73. Thus, as illustrated in FIG. 14, the present example embodiment differs from the fifth example embodiment also in the arrangement of regions in the piezoelectric substrate 2. This is synonymous with the fact that the present example embodiment differs from the first example embodiment illustrated in FIG. 3 in the arrangement of regions in the piezoelectric substrate 2. In other respects, the acoustic wave device according to the present example embodiment has a configuration the same as or similar to that of the acoustic wave device according to the fifth example embodiment.

As illustrated in FIG. 13, some through-holes 13a among all of the through-holes 13a of the first electrode layer 73 are arranged in the electrode finger extending direction. Some through-holes 13a among all of the through-holes 13a are arranged in the electrode finger orthogonal direction. The plurality of cutout portions 13b are arranged in the electrode finger orthogonal direction. In the present example embodiment, the through-holes 13a are disposed in a staggered manner. To be specific, the through-holes 13a that are arranged in the electrode finger orthogonal direction are positioned on the first imaginary line G1.

Thus, as illustrated in FIG. 14, in the piezoelectric substrate 2, some first non-formation regions D among all of the first non-formation regions D are arranged in the electrode finger extending direction. Some first non-formation regions D among all of the first non-formation regions D are arranged in the electrode finger orthogonal direction. The first non-formation regions D are disposed in a staggered manner. To be specific, the first non-formation regions D that are arranged in the electrode finger orthogonal direction are positioned on the first imaginary lines G1.

Also with the present example embodiment, as with the fifth example embodiment, it is possible to identify an acoustic wave device including a piezoelectric substrate 2 including a defect, and it is possible to reduce or prevent the occurrence of a fault in a product including an acoustic wave device. In addition, as with the fifth example embodiment, it is also possible to increase the electrostatic capacitance of an acoustic wave device.

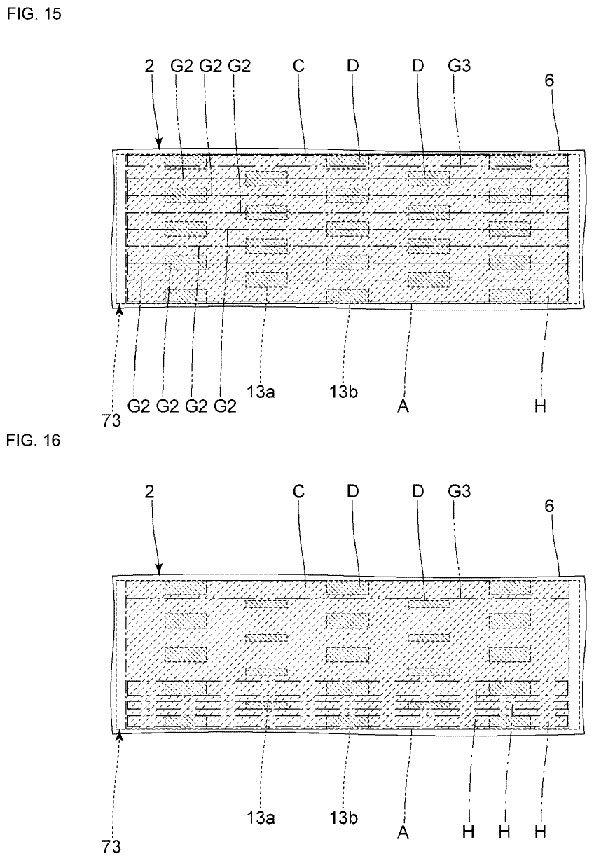

FIG. 15 is a schematic plan view illustrating each region near a portion overlapping the first electrode layer in plan view, second imaginary lines, and a third imaginary line in the seventh example embodiment.

A second imaginary line G2 is an imaginary line that extends in the electrode finger orthogonal direction, that passes through a midpoint between two first non-formation regions D that are adjacent to each other in the electrode finger extending direction, and that extends from one end to the other end of the crossing region A in the electrode finger orthogonal direction. The second imaginary line G2 is a portion of the first imaginary line G1 drawn in FIG. 14. It is also possible to define the second imaginary line G2 in the same or similar way by using the through-holes 13a and the cutout portions 13b of the first electrode layer 73 when seen in plan view. Thus, the second imaginary line G2 will be used in the same or similar way in describing the disposition of the first non-formation regions D, the through-holes 13a, and the cutout portions 13b.

Hereafter, a first length L1 is defined as the total length of portions where the first non-formation regions D are positioned on one second imaginary line G2, and a second length L2 is defined as the total length of portions where the first non-formation regions D are not positioned on one second imaginary line G2. When Rmax is defined as the maximum value and Rmin is defined as the minimum value of the ratio L1/L2 between the first length L1 and the second length L2 for all of the second imaginary lines G2, in the present example embodiment, (Rmax-Rmin)/Rmin is 0. Thus, it is possible to make the acoustic wave propagation velocity in the crossing region A uniform or substantially uniform.

To be more specific, the first length L1 is the same or substantially the same as the total length of portions where the through-holes 13a and the cutout portions 13b illustrated in FIG. 13 are positioned on one second imaginary line G2. A mass is not applied to the piezoelectric substrate 2 by portions where the through-holes 13a and the cutout portions 13b are positioned in the first electrode layer 73. On the other hand, the second length L2 is the same or substantially the same as the total length of portions where the through-hole 13a and the cutout portion 13b are not positioned on one second imaginary line G2. A mass is applied to the piezoelectric substrate 2 by portions where the through-hole 13a and the cutout portion 13b are not positioned in the first electrode layer 73.

Therefore, the ratio L1/L2 is the ratio between the length of a portion where a mass is not applied to the piezoelectric substrate 2 by the first electrode layer 73 and the length of a portion where a mass is applied to the piezoelectric substrate 2 by the first electrode layer 73. Here, “length” refers a dimension in the electrode finger orthogonal direction. The acoustic wave propagation velocity in the crossing region A of the piezoelectric substrate 2 depends on the degree of application of a mass. Thus, the more uniform the ratio L1/L2 in the crossing region A, the more uniform the acoustic wave propagation velocity in the crossing region A.

When (Rmax-Rmin)/Rmin is 0, the ratio L1/L2 is uniform in all portions on the second imaginary line G2. Thus, it is possible to make the acoustic wave propagation velocity in the crossing region A uniform or substantially uniform. Thus, it is possible to reduce or prevent transverse modes, which are unnecessary waves.

It is not necessary that (Rmax−Rmin)/Rmin is 0. It is preferable that (Rmax−Rmin)/Rmin is, for example, about 1.25 or less. Also in this case, the ratio L1/L2 is approximately uniform in the crossing region A. Thus, it is possible to reduce or prevent transverse modes. However, it is more preferable that (Rmax−Rmin)/Rmin is 0.

A third imaginary line G3 drawn in FIG. 15 is an imaginary line that extends in the electrode finger orthogonal direction and that extends from one end to the other end of the crossing region A in the electrode finger orthogonal direction. Although it is possible to draw an infinite number of third imaginary lines G3, FIG. 15 illustrates an example of the third imaginary line G3. Imaginary lines that coincide with the second imaginary lines G2 are also included in a plurality of third imaginary lines G3.

Hereafter, a third length L3 is defined as the total length of portions where the first non-formation regions D are positioned on one third imaginary line G3, and a fourth length L4 is defined as the total length of portions where the first non-formation regions D are not positioned on one third imaginary line G3. A uniform portion H, for example, is defined as a portion where a third imaginary line such that the ratio L3/L4 between the third length L3 and the fourth length L4 is about 1 time or less of the maximum value Rmax and about 1 time or greater of the minimum value Rmin is positioned. In the present example embodiment, the crossing region A includes at least one uniform portion H. To be specific, in the present example embodiment, the crossing region A includes one uniform portion H. To be more specific, the uniform portion H is positioned in the entirety or substantially the entirety of the crossing region A.

In the uniform portion H, the ratio L3/L4 is approximately uniform. Thus, in the uniform portion H, acoustic wave propagation velocity is approximately uniform. In the present example embodiment, the uniform portion H is positioned in the entirety or substantially the entirety of the crossing region A. Accordingly, in the entirety or substantially the entirety of the crossing region A, acoustic wave propagation velocity is approximately uniform. Thus, it is possible to further reduce or prevent transverse modes.

However, the uniform portion H need not be positioned in the entirety or substantially the entirety of the crossing region A. The crossing region A may include a plurality of uniform portions H. This example will be described as a first modification and a second modification of the seventh example embodiment.

FIG. 16 is a schematic plan view illustrating each region near a portion overlapping a first electrode layer in plan view, a third imaginary line, and some uniform portions in the first modification of the seventh example embodiment. In FIG. 16, three uniform portions H that are arranged from a lower portion of FIG. 16 are illustrated, and the other uniform portions H are omitted.

In the first modification, a plurality of uniform portions H are arranged in the electrode finger extending direction. To be more specific, in a portion of the crossing region A, the length L3 in the third imaginary line G3 is about 0. In this portion, the ratio L3/L4 is about 0, and is less than about 1 time Rmin. Therefore, this portion is not a uniform portion H. Uniform portions H and portions that are not uniform portions H are alternately arranged in the electrode finger extending direction.

In the first modification, for example, the total area of all of the uniform portions is about 80% or greater of the area of the crossing region A. Thus, it is possible to effectively make acoustic wave propagation velocity in the crossing region A uniform or substantially uniform. Thus, it is possible to effectively reduce or prevent transverse modes.

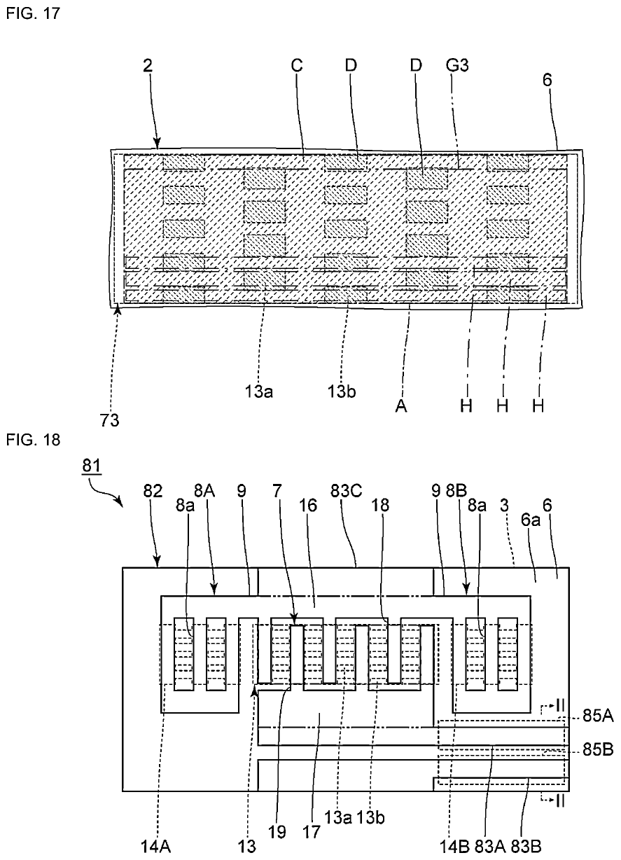

FIG. 17 is a schematic plan view illustrating each region near a portion overlapping a first electrode layer in plan view, a third imaginary line, and some uniform portions in a second modification of the seventh example embodiment of the present invention. In FIG. 17, three uniform portions H that are arranged from a lower portion of FIG. 17 are illustrated, and the other uniform portions H are omitted.

In the second modification, for example, in a portion of the crossing region A, the ratio L3/L4 based on regions on the third imaginary line G3 is greater than about 1 time Rmax. Therefore, this portion is not a uniform portion H. Uniform portions H and portions that are not uniform portions H are arranged alternately in the electrode finger extending direction.

In the second modification, for example, the total area of all of the uniform portions H is about 80% or greater of the area of the crossing region A. Thus, it is possible to effectively make acoustic wave propagation velocity in the crossing region A uniform. Thus, it is possible to effectively reduce or prevent transverse modes.

With the first modification and the second modification, as with the seventh example embodiment, it is possible to identify an acoustic wave device including a piezoelectric substrate 2 including a defect, and it is possible to reduce or prevent the occurrence of a fault in a product including an acoustic wave device. Moreover, it is also possible to increase the electrostatic capacitance of an acoustic wave device.

In the seventh example embodiment, the first modification, and the second modification, the plurality of first non-formation regions D are arranged at a period that is an integer multiple of the electrode finger pitch in the electrode finger orthogonal direction. Thus, it is possible to more easily observe the support substrate 3 side, and it is possible to improve the resonance characteristics of an acoustic wave device.

As described above, it is possible to use an acoustic wave device according to an example embodiment of the present invention in a filter device or the like. For example, an acoustic wave device according to an example embodiment of the present invention may include a wiring line provided on a piezoelectric layer. An acoustic wave device according to an example embodiment the present invention may include an electrode layer other than a first electrode layer and a second electrode layer. This example will be described in an eighth example embodiment of the present invention.

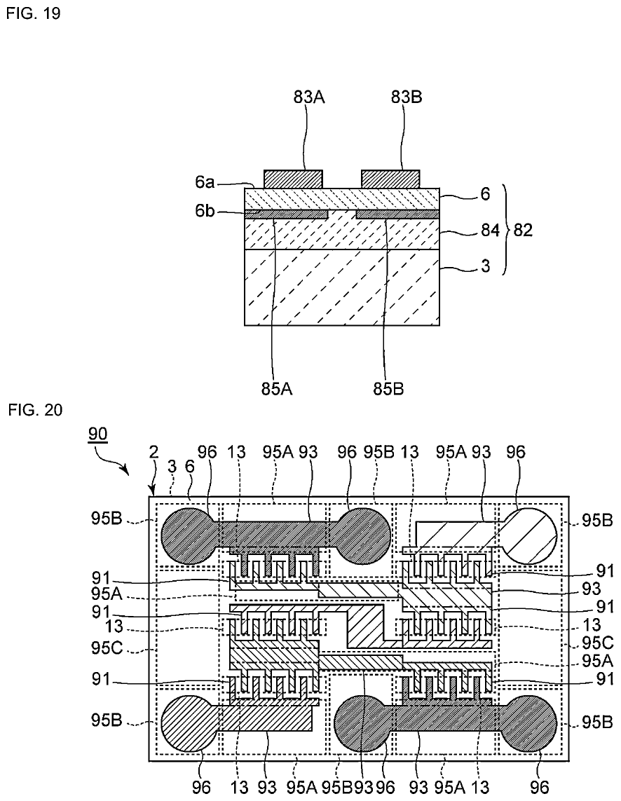

FIG. 18 is a schematic plan view of an acoustic wave device according to the eighth example embodiment. FIG. 19 is a schematic sectional view taken along line II-II in FIG. 18. In FIG. 18, the boundaries between wiring lines and the first and second busbars 16 and 17 are shown by two-dot chain lines.

As illustrated in FIG. 18, the present example embodiment differs from the first example embodiment in that an acoustic wave device 81 includes a plurality of wiring lines and a plurality of third electrode layers. To be specific, the plurality of third electrode layers in the present example embodiment include a third electrode layer 85A and a third electrode layer 85B. As illustrated in FIG. 19, the present example embodiment differs from the first example embodiment also in the stacking configuration of a piezoelectric substrate 82. In other respects, the acoustic wave device 81 according to the present example embodiment has a configuration the same as or similar to that of the acoustic wave device 1 according to the first example embodiment.

The piezoelectric substrate 82 includes the support substrate 3, an intermediate layer 84, and the piezoelectric layer 6. In the present example embodiment, the intermediate layer 84 is a single-layer dielectric film. To be specific, for example, silicon oxide is used as the material of the intermediate layer 84. However, the material of the intermediate layer 84 is not limited to the above. The support substrate 3, the intermediate layer 84, and the piezoelectric layer 6 are stacked in this order.

As illustrated in FIG. 18, the plurality of wiring lines of the acoustic wave device 81 are provided on the first main surface 6a of the piezoelectric layer 6. To be specific, the plurality of wiring lines include a first wiring line 83A, a second wiring line 83B, and a third wiring line 83C. The first wiring line 83A and the third wiring line 83C are connected to the IDT electrode 7. To be more specific, the first wiring line 83A is connected to the second busbar 17 of the IDT electrode 7. The third wiring line 83C is connected to the first busbar 16 of the IDT electrode 7. Thus, the first wiring line 83A and the third wiring line 83C are connected to different potentials.

On the other hand, the second wiring line 83B is not connected to the IDT electrode 7. The second wiring line 83B is connected to a potential different from the potential to which the first wiring line 83A is connected. The second wiring line 83B may be connected to, for example, an element other than the acoustic wave device 81. Alternatively, if the first wiring line 83A is not connected to the ground potential, the second wiring line 83B may be connected to the ground potential.

The third electrode layer 85A and the third electrode layer 85B are provided between the support substrate 3 and the piezoelectric layer 6. To be more specific, as illustrated in FIG. 19, the third electrode layer 85A and the third electrode layer 85B are provided directly on the second main surface 6b of the piezoelectric layer 6. The third electrode layer 85A and the third electrode layer 85B are not in contact with each other. Although not illustrated, a first electrode layer and each second electrode layer are directly provided on the second main surface 6b of the piezoelectric layer 6.

The third electrode layer 85A overlaps the first wiring line 83A in plan view. The third electrode layer 85B overlaps the second wiring line 83B in plan view. Thus, the third electrode layer 85A and the third electrode layer 85B define and function as electromagnetic shields for the first wiring line 83A and the second wiring line 83B. Thus, it is possible to reduce or prevent an electrical influence from the support substrate 3 side or from the outside.

In the present example embodiment, the third electrode layer 85A and the third electrode layer 85B are not in contact with each other. Thus, it is possible to reduce or prevent a mutual electrical influence between the first wiring line 83A and the second wiring line 83B that are connected to different potentials. One third electrode layer may overlap the first wiring line 83A and the second wiring line 83B in plan view. Also in this case, the third electrode layer defines and functions as an electromagnetic shield for the first wiring line 83A and the second wiring line 83B.

Referring back to FIG. 18, the third electrode layer 85A and the third electrode layer 85B do not overlap the IDT electrode 7, the reflector 8A, and the reflector 8B in plan view. Thus, it is possible to increase the heat dissipation of a portion where the IDT electrode 7 and each reflector are not provided.

In the acoustic wave device 81, the first electrode layer 13 overlaps the IDT electrode 7 in plan view. The second electrode layer 14A overlaps the reflector 8A in plan view. The second electrode layer 14B overlaps the reflector 8B in plan view. Thus, it is also possible to increase the heat dissipation of portions where the IDT electrode 7 and each reflector are provided. In these ways, with the present example embodiment, it is possible to increase the heat dissipation of the acoustic wave device 81.

In the present example embodiment, the first electrode layer 13, the second electrode layer 14A, and the second electrode layer 14B are configured the same as or similar to those in the first example embodiment. Thus, it is possible to identify an acoustic wave device 81 including a piezoelectric substrate 82 having a defect, and it is possible to reduce or prevent the occurrence of a fault in a product including an acoustic wave device 81. In addition, as with the first example embodiment, it is also possible to increase the electrostatic capacitance of an acoustic wave device.

The arrangement of the plurality of third electrode layers in the acoustic wave device 81 is not limited to the above. It is sufficient that a plurality of third electrode layers do not overlap the crossing region in plan view. For example, the plurality of third electrode layers need not overlap any of a plurality of wiring lines in plan view. Also in this case, because the plurality of third electrode layers are provided, it is possible to increase the heat dissipation of a portion other than the crossing region.

It is preferable that the third electrode layer does not overlap each reflector in plan view. In this case, it is possible to arrange each second electrode layer so as to overlap each reflector in plan view. Thus, it is possible to more reliably identify an acoustic wave device 81 including a piezoelectric substrate 82 including a defect.

It is preferable that the main component of the material of each third electrode layer is the same as the main component of the material of the first electrode layer 13. Similarly, it is preferable that the main component of the material of each second electrode layer be the same as the main component of the material of the first electrode layer 13. Thus, unevenness in the application of a mass to the piezoelectric substrate 82 does not easily occur, and stress concentration does not easily occur. In the present specification, “main component” refers to a component included by about 50% or more.

The acoustic wave device 81 includes two third electrode layers 85A and the third electrode layer 85B as the plurality of third electrode layers. However, it is sufficient that the acoustic wave device 81 include at least one third electrode layer.

Hereafter, an example of a filter device in which a plurality of acoustic wave device each including a plurality of third electrode layers are used will be described. Hereafter, a first busbar and a second busbar may be simply referred to as “busbar”.

FIG. 20 is a schematic plan view of a filter device according to a ninth example embodiment of the present invention. In FIG. 20, each reflector and each second electrode layer are omitted. In FIG. 20, through-holes and cutout portions in each first electrode layer 13 are also omitted. In FIG. 20, the boundary between each busbar and a wiring line is shown by a two-dot chain line. In FIG. 20, electrodes that are provided on the first main surface 6a of the piezoelectric layer 6 and connected to different potentials are shown by different hatching patterns.

A filter device 90 is a ladder filter, for example. To be specific, the filter device 90 includes serial-arm resonators and two parallel-arm resonators. In the present example embodiment, all of the serial-arm resonators and all of the parallel-arm resonators are acoustic wave devices according to example embodiments of the present invention. Each acoustic wave device 91 in the present example embodiment shares the same piezoelectric substrate 2. The stacking configuration of the piezoelectric substrate 2 is the same as or similar to that in the first example embodiment.

The first electrode layer 13 of each acoustic wave device 91 is configured the same as or similar to that in the first example embodiment. Therefore, it is possible to identify an acoustic wave device 91 if the acoustic wave device 91 includes a defective substrate in a process of obtaining these acoustic wave devices 91. Thus, it is possible to more reliably use, as an acoustic wave resonator of the filter device 90, each acoustic wave device 91 that does not include a defect. Accordingly, it is possible to reduce or prevent the occurrence of a fault in the filter device 90.

Each acoustic wave device 91 of the filter device 90 includes at least one wiring line 93. That is, the filter device 90 includes a plurality of wiring lines 93. The acoustic wave devices 91 are connected to each other by some wiring lines 93 among all of the wiring lines 93. The filter device 90 includes a plurality of electrode pads 96. The plurality of electrode pads 96 and the plurality of acoustic wave devices 91 are connected by some wiring lines 93 among all of the wiring lines 93. The filter device 90 is connected to a signal potential or a ground potential via the plurality of electrode pads 96.

In the present example embodiment, the electrode pad 96 or the busbar of the acoustic wave device 91 and the wiring line 93 are integrally provided. However, the electrode pad 96 and the wiring line 93 may be independently made of different materials, and may be connected to each other. The busbar and the wiring line 93 may be independently made of different materials, and may be connected to each other.

The filter device 90 includes, as a plurality of third electrode layers, a plurality of third electrode layers 95A, a plurality of third electrode layers 95B, and a plurality of third electrode layers 95C. Each acoustic wave device 91 includes at least one third electrode layer among the third electrode layer 95A, the third electrode layer 95B, and the third electrode layer 95C.

The plurality of third electrode layers 95A, the plurality of third electrode layers 95B, and the plurality of third electrode layers 95C are each provided between the support substrate 3 and the piezoelectric layer 6. To be more specific, as with the first electrode layer 13 in the first example embodiment illustrated in FIG. 2, the plurality of third electrode layers 95A, the plurality of third electrode layers 95B, and the plurality of third electrode layers 95C are provided on the intermediate layer 4 side of the dielectric layer 5. The plurality of third electrode layers 95A, the plurality of third electrode layers 95B, and the plurality of third electrode layers 95C are not in contact with each other.

As illustrated in FIG. 20, the third electrode layer 95A overlaps the wiring line 93 and the busbar in plan view. The third electrode layer 95B overlaps the electrode pad 96 in plan view. The third electrode layer 95C does not overlap any of the wiring line 93 and the electrode pad 96 in plan view.

Because the plurality of third electrode layers 95A, the plurality of third electrode layers 95B, and the plurality of third electrode layers 95C are provided, as with the eighth example embodiment, it is possible to reduce or prevent an electrical influence from the support substrate 3 side or from the outside. In addition, because the plurality of third electrode layers 95A, the plurality of third electrode layers 95B, and the plurality of third electrode layers 95C are not in contact with each other, it is possible to reduce or prevent a mutual electrical influence between the wiring lines 93 and the electrode pads 96 having different potentials.

The third electrode layer 95C is positioned between two third electrode layers 95B. These third electrode layers 95B respectively overlap in plan view the electrode pads 96 that are connected to different potentials. In this case, the third electrode layer 95C defines and functions as an electromagnetic shield between the two third electrode layers 95B. This configuration is particularly preferable when the two third electrode layer 95B respectively overlap in plan view the electrode pads 96 that are connected to different signal potentials. To be specific, it is possible to effectively reduce or prevent a mutual electrical influence between the electrode pads 96.

Alternatively, the third electrode layer 95C may be positioned between the third electrode layer 95A and the third electrode layer 95B that respectively overlap in plan view the wiring line 93 and the electrode pad 96 that are connected to different signal potentials. In this case, it is possible to effectively reduce or prevent a mutual electrical influence between the wiring line 93 and the electrode pad 96.

The third electrode layer 95C may be positioned between the third electrode layers 95A that respectively overlap in plan view the wiring lines 93 that are connected to different signal potential. In this case, it is possible to reduce or prevent a mutual electrical influence between the wiring lines 93.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer including a first main surface and a second main surface facing each other and a support substrate stacked on a second main surface side of the piezoelectric layer;
at least one first electrode layer between the support substrate and the piezoelectric layer and not connected to a signal potential; and
an IDT electrode on the first main surface of the piezoelectric layer and including a plurality of electrode fingers; wherein
when an electrode finger extending direction is defined as a direction in which the plurality of electrode fingers extend and the IDT electrode is seen from a direction orthogonal or substantially orthogonal to the electrode finger extending direction, a region where electrode fingers of the plurality of electrode fingers adjacent to each other overlap is a crossing region;
the first electrode layer is provided at least at a position overlapping the crossing region in plan view;
the piezoelectric substrate includes a first formation region overlapping the crossing region and overlapping the first electrode layer in plan view and a first non-formation region overlapping the crossing region and not overlapping the first electrode layer in plan view; and
the first non-formation region overlaps in plan view at least one of portions between the electrode fingers adjacent to each other.

2. The acoustic wave device according to claim 1, wherein
at least one through-hole is provided in the first electrode layer; and
the first non-formation region includes a region of the piezoelectric substrate overlapping the through-hole in plan view.

3. The acoustic wave device according to claim 1, wherein
at least one cutout portion is provided in the first electrode layer; and
the first non-formation region includes a region of the piezoelectric substrate overlapping the cutout portion in plan view.

4. The acoustic wave device according to claim 1, wherein the at least one first electrode layer includes only one first electrode layer.

5. The acoustic wave device according to claim 1, further comprising:
a plurality of the first electrode layers; wherein
the first non-formation region includes a region of the piezoelectric substrate overlapping in plan view a portion between the first electrode layers that are adjacent to each other.

6. The acoustic wave device according to claim 1, wherein
the piezoelectric substrate includes a plurality of the first non-formation regions; and
at least some of the plurality of first non-formation regions are arranged at a period that is an integer multiple of an electrode finger pitch of the IDT electrode in the direction orthogonal or substantially orthogonal to the electrode finger extending direction.

7. The acoustic wave device according to claim 6, wherein
some of the plurality of first non-formation regions are arranged at a period that is an integer multiple of the electrode finger pitch of the IDT electrode in the direction orthogonal or substantially orthogonal to the electrode finger extending direction, and others of the plurality of first non-formation regions are arranged in the electrode finger extending direction; and
when a first imaginary line is defined as an imaginary line extending in the direction orthogonal or substantially orthogonal to the electrode finger extending direction and passing through a midpoint between first non-formation regions of the plurality of non-formation regions adjacent to each other in the electrode finger extending direction, the plurality of first non-formation regions are not located on any of the first imaginary lines.

8. The acoustic wave device according to claim 1, wherein
some of the plurality of first non-formation regions are arranged in the direction orthogonal or substantially orthogonal to the electrode finger extending direction, and others of the plurality of first non-formation regions are arranged in the electrode finger extending direction; and
when a first imaginary line is defined as an imaginary line extending in the direction orthogonal or substantially orthogonal to the electrode finger extending direction and passing through a midpoint between first non-formation regions of the plurality of first non-formation regions adjacent to each other in the electrode finger extending direction, the plurality of the first non-formation regions that are arranged in the direction orthogonal to the electrode finger extending direction are located on the first imaginary line.

9. The acoustic wave device according to claim 8, wherein, when a second imaginary line is defined as an imaginary line extending in the direction orthogonal or substantially orthogonal to the electrode finger extending direction, passing through a midpoint between two of the plurality of first non-formation regions adjacent to each other in the electrode finger extending direction, and extending from one end to another end of the crossing region in the direction orthogonal or substantially orthogonal to the electrode finger extending direction, a first length L1 is defined as a total length of portions where the plurality of first non-formation regions are located on one of second imaginary lines, a second length L2 is defined as a total length of portions where the plurality of first non-formation regions not located on one of the second imaginary lines, and Rmax is defined as a maximum value and Rmin is defined as a minimum value of a ratio L1/L2 between the first length L1 and the second length L2 for all of the second imaginary lines, (Rmax−Rmin)/Rmin is about 1.25 or less.

10. The acoustic wave device according to claim 9, wherein, when a third imaginary line is defined as an imaginary line extending in the direction orthogonal or substantially orthogonal to the electrode finger extending direction and extending from one end to another end of the crossing region in the direction orthogonal or substantially orthogonal to the electrode finger extending direction, a third length L3 is defined as a total length of portions where the plurality of first non-formation regions are located on one of the third imaginary lines, a fourth length L4 is defined as a total length of portions where the plurality of first non-formation regions are not located on one of the third imaginary lines, and a uniform portion is defined as a portion where the third imaginary line such that a ratio L3/L4 between the third length L3 and the fourth length L4 is about 1 time or less of the maximum value Rmax and about 1 time or greater of the minimum value Rmin is located, the crossing region includes at least one of the uniform portions; and
a total area of all uniform portions is about 80% or greater of an area of the crossing region.

11. The acoustic wave device according to claim 1, wherein an entirety or substantially an entirety of the plurality of first non-formation regions overlaps in plan view a portion between the plurality of electrode fingers.

12. The acoustic wave device according to claim 1, further comprising:
a pair of reflectors on the first main surface of the piezoelectric substrate facing each other with the IDT electrode therebetween in the direction orthogonal or substantially orthogonal to the electrode finger extending direction and each of which includes a plurality of reflector electrode fingers; and
at least one second electrode layer between the support substrate and the piezoelectric layer, not connected to a signal potential, and overlapping the reflectors in plan view; wherein
a region where the plurality of reflector electrode fingers adjacent to each other overlap when each of the reflectors is seen from the direction orthogonal or substantially orthogonal to the electrode finger extending direction is a reflector crossing region of each of the reflectors;
the piezoelectric substrate includes a second formation region overlapping the reflector crossing region and overlapping the second electrode layer in plan view and a second non-formation region overlapping the reflector crossing region and not overlapping the second electrode layer in plan view; and
the second non-formation region overlaps in plan view at least one of portions between the plurality of reflector electrode fingers that are adjacent to each other.

13. The acoustic wave device according to claim 12, wherein the first electrode layer and the second electrode layer are not connected.

14. The acoustic wave device according to claim 1, wherein the piezoelectric substrate includes a dielectric layer between the piezoelectric layer and the first electrode layer.

15. The acoustic wave device according to claim 1, wherein
the piezoelectric substrate includes an intermediate layer between the piezoelectric layer and the support substrate; and
a portion of the intermediate layer is located between the first electrode layer and the support substrate.

16. The acoustic wave device according to claim 1, wherein
a hollow portion is provided in the piezoelectric substrate; and
the first electrode layer is provided in the hollow portion.

17. The acoustic wave device according to claim 1, further comprising at least one third electrode layer between the support substrate and the piezoelectric layer and not overlapping the crossing region in plan view.

18. The acoustic wave device according to claim 17, further comprising:
at least one wiring line on the first main surface of the piezoelectric layer; wherein
the at least one wiring line includes a first wiring line connected to the IDT electrode; and
the third electrode layer overlaps the first wiring line in plan view.

19. The acoustic wave device according to claim 18, further comprising:
a plurality of the third electrode layers; and
a plurality of the wiring lines; wherein
the plurality of wiring lines include a second wiring line connected to a potential different from a potential to which the first wiring line is connected; and
the plurality of third electrode layers include two of the third electrode layers not in contact with each other, one of the two third electrode layers not in contact with each other overlaps the first wiring line in plan view, and another of the two third electrode layers not in contact with each other overlaps the second wiring line in plan view.
